(19) United States
(12) Patent Application Publication
(10) Pub. No.: US 2005/0057273 A1
(43) Pub. Date: Mar. 17, 2005

(54) Built-in testing apparatus for testing displays and operation method thereof

(75) Inventors: Hsiao-Yi Lin, Hsinchu City (TW); Chang-Ming Chao, Hsinchu City (TW)

Correspondence Address: LIU & LIU, 811 WEST SEVENTH STREET, SUITE 1100, LOS ANGELES, CA, 90017, US

(73) Assignee: Toppoly Optoelectronics Corp.

(21) Appl. No.: 10/887,374

(22) Filed: Jul. 6, 2004

(30) Foreign Application Priority Data
Sep. 12, 2003 (TW) 92125152

(51) Int. Cl. G01R 31/00

(52) U.S. Cl. 324/770

(57) ABSTRACT

A testing apparatus for testing a display and an operation method of the testing apparatus are disclosed. The apparatus is electrically coupled to a driving line of a display, an image signal source and a shorting bar signal source comprises a first bonding pad, n probing terminals and n switch devices. In the present invention, the n probing terminals are electrically coupled to the first bonding pad, where the n is an integer not less than 1. The gate terminal of each switch device is electrically coupled to the shoring bar signal source, the first terminal is electrically coupled to the image signal source and the second terminal is electrically coupled to one of the n probing terminals. In the present invention, the voltage provided by the shorting bar signal source controls serving as a shorting bar test or a full contact test for testing the display.

### CROSS-REFERENCE TO RELATED APPLICATION

This application claims the priority benefit of Taiwan application serial no. 92125152, filed Sep. 12, 2003.

### BACKGROUND OF THE INVENTION

1. Field of the Invention

The present invention relates to a built-in or on-board testing apparatus for testing a display, and more particularly to a testing apparatus for testing a display and an operation method of the testing apparatus serving for the shorting bar test and full contact test.

2. Description of the Related Art

Being discovered in Europe, researched and developed in the United States, and its physical properties being conferred in Japan upon different fields of application, liquid crystal has served as a key component for flat panel displays. For the time being, a variety of techniques have been widely applied in displays, especially in liquid crystal displays, such as twisted nematic-liquid crystal displays (TN-LCD), super twisted nematic-liquid crystal displays (STN-LCD), and thin film transistor liquid crystal displays (TFT LCD). During the manufacturing for quality control purposes, TFT LCD must pass either the shorting bar test or the full contact test for ensuring that the TFT LCD operates normally.

Referring to FIG. 2, it is a circuit illustrating a prior art testing apparatus for testing a display in a shorting bar test. As demonstrated in FIG. 2, the display 200 includes a testing apparatus 210, a gate driving circuit 250, and an array of display units 251, each coupled to a gate driving line 252 from gate driving circuit 250 and a data driving line 222 from data driving circuit (not shown). Each display unit 251 includes a transistor 254, a capacitor 256 and a pixel cell 258. FIG. 2 schematically shows one display unit 251; there may be many display units in the array.

In FIG. 2, the testing apparatus 210 is coupled to the display units 251 as shown. The testing apparatus 210 includes a data bonding pad 220, a gate bonding pad 230, a bonding pad 240 for the other circuits, a probing terminal P₁₁ corresponding to the data bonding pad 220, probing terminals P₄₀ and P₂₀˜P₂₉ corresponding to the gate bonding pad 230, and probing terminals P₃₀˜P₃₉ corresponding to the other circuit bonding pad 240. Each of the probing terminals P₁₁, P₂₀˜P₂₉, P₃₀˜P₃₉ and P₄₀ is electrically coupled to a resistor 212.

When the testing apparatus 210 serves a shorting bar test, all probing terminals are grounded, the data bonding pad 220 is electrically coupled to an image signal source and a resistor 216 is electrically coupled between the data bonding pad 220 and the image signal source. Then, the shorting bar test is applied to the display 200 by the image signals from the image signal source.

Please referring to FIG. 3, it is a circuit illustrating a conventional testing apparatus for performing a full contact test for a display. The difference between FIGS. 2 and 3 is that the data bonding pad 220 in FIG. 3 is electrically coupled to the probing terminals P₁₀₁˜P₁₂₈ and that the gate bonding pad 230 is electrically coupled to the probing terminals P₂₀˜P₂₉. Additionally, there is no image signal source in FIG. 3.

Under the measurement of the full contact test, the probing terminals P₁₀₁˜P₁₂₈ driven by data signal transmitted from a test bed (not shown), P₂₀˜P₂₉ and P₃₀˜P₃₉ driven by the timing control of the test bed (not shown) are all coupled to each other. Then, the full contact test to the display 300 is activated.

Accordingly, conventional testing only allows for either shorting bar testing or full contact testing, but not both. The conventional testing apparatus for testing a display has following disadvantages:
(1) The conventional shorting bar test for testing a display is performed after the process of scribing and breaking the substrate. In addition, during the shorting bar test an operator is capable of determining whether a display is normal or abnormal by visual inspection, but not distinguishing the failed data driving line since a single-color image signal, such as a red signal, is input thereto.
(2) During the conventional full contact test for testing a display, although it is possible to detect a failed data driving line with a sophisticated probe, the cost of accurate probing system is substantially high and thus is not desirable for mass production.
   It would be desirable to provide a testing apparatus that would overcome the drawbacks of both the conventional testing approaches.

### SUMMARY OF THE INVENTION

The present invention overcomes the drawbacks in the prior art by providing an integrated, built-in structure in the display panel that would allow for full contact test and shorting bar test, activated by a switch that switches between a full contact test mode and a shorting bar test mode.

In one aspect, the present invention discloses a testing apparatus of testing a display and an operation method thereof, which includes a shorting bar signal source and a switch device. The switch device is turned on when the shorting bar signal source provides a high voltage for serving a shorting bar test at the probing terminal. Whereas the switch device is turned off when the shorting bar signal source provides a low voltage for serving a full contact test at the probing terminal.

In one embodiment, the present invention discloses a testing apparatus for testing a display, which is electrically coupled to a first driving line, an image signal source and a shorting bar signal source. The testing apparatus comprises a first bonding pad, n probing terminals and n switch devices, wherein the first bonding pad is electrically coupled to the first driving line.

According to one embodiment of the present invention, the n probing terminals are electrically coupled to the first bonding pad, and the n is an integer not less than 1, wherein the probing terminals serve as a shorting bar test or a full contact test.

According to one embodiment of the present invention, each switch device has a gate terminal, a first terminal and a second terminal. Wherein the gate terminal of each switch device is electrically coupled to the shorting bar signal source, the first terminal of each switch device is electrically coupled to the image signal source, and the second terminal of each switch device is electrically coupled to one of the n probing terminals.

According to one embodiment of the present invention, the testing apparatus for testing a display serves the shorting bar test or the full contact test by the voltage from the shorting bar signal source. If the shorting bar signal source provides a high voltage, each switch device is turned on for serving the shorting bar test; on the contrary, if the shorting bar signal source provides a low voltage, each switch device is turned off for serving the full contact test.

According to one embodiment of the present invention, the testing apparatus for testing a display further comprises a second bonding pad electrically coupled to m probing terminals for serving the full contact test, wherein m is an integer not less than 1.

According to one embodiment of the present invention, the testing apparatus for testing a display further comprises a third bonding pad electrically coupled to s probing terminals for serving the full contact test, wherein s is an integer not less than 1.

The present invention discloses an operation method of a testing apparatus for testing a display, which comprises the shorting bar signal source providing a signal to the gate terminal of the switch device. The switch device determines whether to turn on or off the switch device according to a voltage supplied by the shorting bar signal source. When the switch device is turned on, the probing terminals serve as the image signal measurement, i.e. the shorting bar test; on the contrary, when the switch device is turned off, the probing terminals serve as the full contact test.

According to one embodiment of the present invention, the operation method described above further comprises performing the full contact test at a second bonding pad and a third bonding pad.

Since a switch device is adopted to the testing apparatus of the present invention, the shorting bar test is performed when the shorting bar signal source provides a high voltage level, and the full contact test is performed when the shorting bar signal source provides a low voltage,

In order to make the aforementioned and other objects, features and advantages of the present invention understandable, an embodiment accompanied with figures is described in detail hereinafter.

### BRIEF DESCRIPTION OF THE DRAWINGS

FIG. 1A is a schematic circuit diagram illustrating an exemplary testing apparatus for testing a display according to one embodiment of the present invention.

FIG. 1B is an operation flow chart of the testing apparatus for testing a display in accordance with one embodiment of the present invention.

FIG. 2 is a schematic circuit diagram illustrating conventional testing apparatus for testing a display in a shorting bar test.

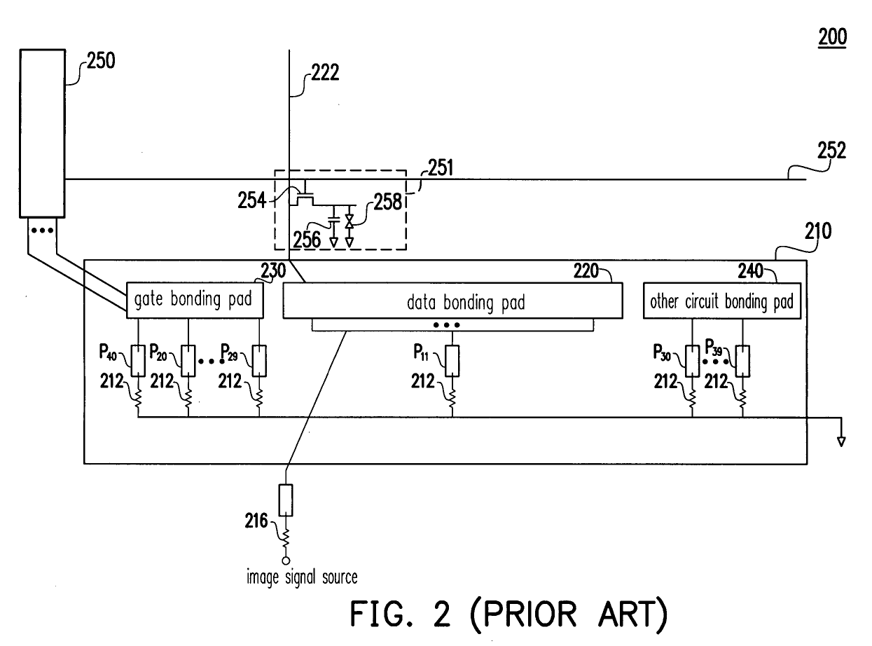

FIG. 3 is a schematic circuit diagram illustrating conventional testing apparatus for testing a display in a full contact test.

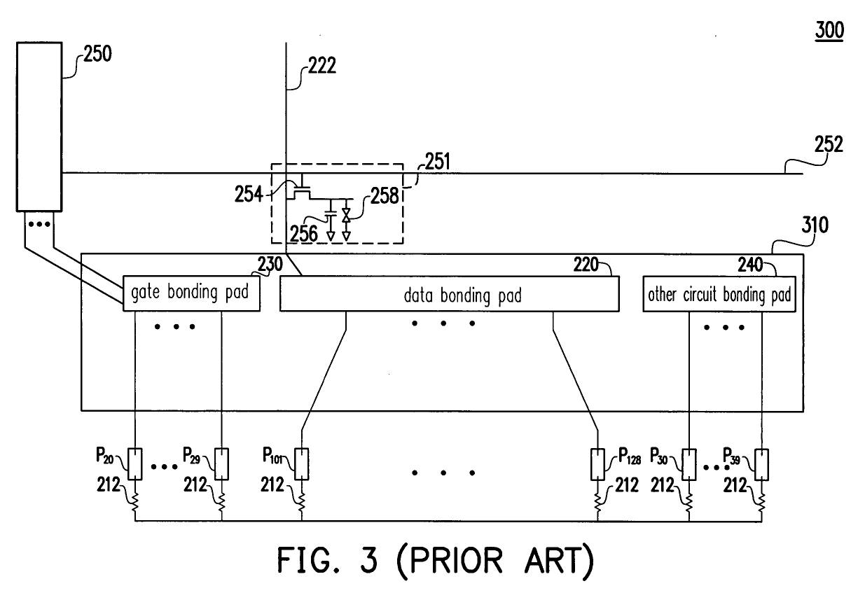

### DESCRIPTION OF THE EMBODIMENTS

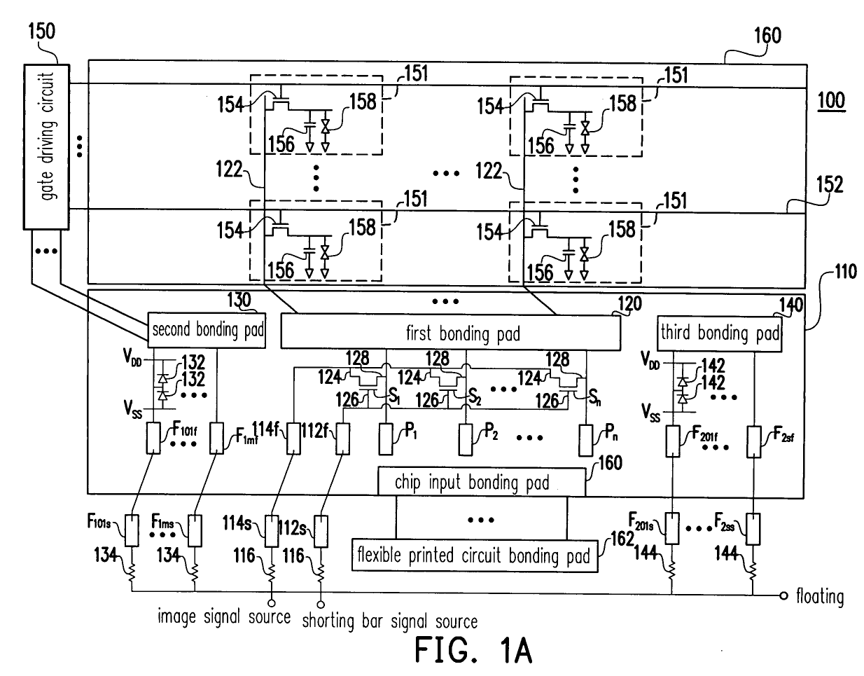

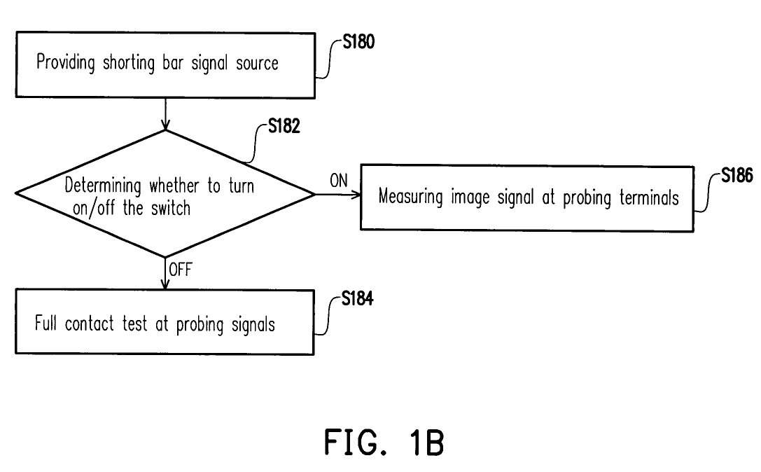

Referring to FIG. 1A, it is a circuit drawing showing an exemplary testing apparatus for testing a display. In FIG. 1A, the display 100 includes a testing apparatus 110, a display area 160 having a plurality of display units 151 arranged as an array, a gate driving circuit 150, a plurality of first driving lines 122 and a plurality of gate driving lines 152. Each display unit 151 of the display area 160 includes a transistor 154, a capacitor 156 and a pixel cell 158. Additionally, it is understandable to one of skill in the art that the testing apparatus 110 can be a data driving circuit, the first driving line 122 can be a data driving line, and the pixel cell 158 can be a liquid crystal capacitor or organic light emission display (OLED) layer, without limitation of the scope thereto.

Referring to FIG. 1A, the testing apparatus 110 is electrically coupled to the first driving line 122, an image signal source and a shorting bar signal source. The testing apparatus 110 has a first bonding pad 120 for transmitting data signal, n probing terminals P₁˜Pₙ and n switch devices S₁˜Sₙ, wherein the n is a positive integer not less than 1.

In the embodiment of the present invention, the first bonding pad 120 is electrically coupled to the first driving line 122 and the n probing terminals P₁˜Pₙ, and each switch device S₁˜Sₙ has a gate terminal 126, a first terminal 124 (source or drain) and a second terminal 128 (drain or source). The gate terminal 126 of each switch device S₁˜Sₙ is electrically coupled to the shorting bar signal source, the first terminal 124 of each switch device S₁˜Sₙ is electrically coupled to the image signal source, and the second terminal 128 of each switch device S₁˜Sₙ is electrically coupled to one of the probing terminals P₁˜Pₙ.

In the embodiment of the present invention, the testing apparatus 110 for testing a display serving the shorting bar test or the full contact test depends on the voltage supplied from the shorting bar signal source. If the shorting bar signal source provides a high voltage (V_{DD}), each switch device S₁˜Sₙ is turned on and the probing terminals P₁˜Pₙ serve the shorting bar test. On the contrary, if the shorting bar signal source provides a low voltage (V_{SS}), each switch device S₁˜Sₙ is turned off and the probing terminals P₁˜Pₙ serve the full contact test. Alternatively, each of the switch devices S₁˜Sₙ can be turned on for serving the shorting bar test when the shorting bar signal source provides a low voltage (V_{SS}) and for serving the full contact test when the shorting bar signal source provides a high voltage (V_{DD}).

In the embodiment of the present invention, a resistor 116 is electrically coupled between the shoring bar signal source and the gate terminal 126 of the first switch device Si, whereas another resistor 116 is electrically coupled between the image signal source and the first terminal 124 of the first switch device S₁. When the input signal is substantially beyond a tolerated high voltage, the resistors 116 can serve to reduce the voltage and protect the internal circuit of the testing apparatus from damage, but is not limited thereto.

In the embodiment in the present invention, the testing apparatus 110 further comprises a second bonding pad 130 and a third bonding pad 140. The second bonding pad 130 is electrically coupled to the gate terminal driving circuit 150 and m probing terminals F₁₀₁˜F₁ₘ for transmitting control signals, and the third bonding pad 140 is electrically coupled to other control circuits (not shown) and s probing terminals F₂₀₁˜F₂ₛ for transmitting power signals, wherein the m and s are integers not less than 1.

In the embodiment, each probing terminal F₁₀₁˜F₁ₘ and each probing terminal F₂₀₁˜F₂ₛ are coupled to resistors 134 and 144, respectively, which serve the same function as the resistor 116.

Referring FIG. 1A. When the display 100 is under the shorting bar test, the probing terminal 112 of the shorting bar signal source is then coupled to a high voltage V_{DD}, and the probing terminal 114s of the image signal source is coupled to the image signal source. Then, the high voltage provided from the shorting bar signal source turns on each of the switch devices S₁˜Sₙ and the probing terminal 114s serves measuring the signals from the image signal source for determining whether the operation of the circuit is normal.

When the display 100 is under the full contact test, the probing terminal 112f of the shorting bar signal source is coupled to a low voltage V_{SS}, and the probing terminal 114f of the image signal source is floating. Then, the probing terminals P₁˜Pₙ, F₁₀₁˜F₁ₘ and F₂₀₁˜F₂ₛ serve for full contact test for determining whether the circuit operates normally.

In the embodiment of the present invention, the input of image signals can control gray level.

In the embodiment of the present invention, the testing apparatus 110 further comprises coupling the second bonding pad 130 and the first probing terminal F₁₀₁ to an electrostatic discharge protection circuit composed of two transistors 132, and coupling the third bonding pad 140 and the first probing terminal F₂₀₁ to an electrostatic discharge protection circuit composed of two transistors 142, but not limited thereto.

In the embodiment of the present invention, the testing apparatus 110 further comprises a chip input bonding pad 160 and a flexible printed circuit (FPC) bonding pad 162 electrically coupled thereto. The FPC bonding pad 162 coupled to compatible chip input bonding pad 160 is commonly used in a LCD panel circuit for its flexibility and 3-dimensional routing, but is exemplary which does not limit the scope of the present invention.

Referring to FIG. 1B, it is an operation flow chart of the operation method of the testing apparatus for testing a display in accordance with the embodiment of the present invention. Referring to FIG. 1A together with FIG. 1B, it is noted that the operation method according to the embodiment of the present invention includes providing a control voltage, e.g. V_{DD}, to the shorting bar signal source terminal then to the gate terminal of the switch devices S₁˜Sₙ of the testing apparatus in step s180, and determining whether to turn on or off the switch devices S₁˜Sₙ according to the voltage given at the shorting bar signal source via probing terminal 112 from a testing bed (not shown) in step s182. In step s186, when the switch devices S₁˜Sₙ are turned on, the probing terminals serve for measuring inputting image signals provided from the image signal source via the probing terminal 114, i.e. performing the shorting bar test. On the contrary, in step s184 when the switch devices are turned off by the control voltage, e.g. V_{SS}, given at the shoring bar signal source terminal via the probing terminal 112, the probing terminals serve for the full contact test. It is noted that the control voltage given at the shorting bar signal source is not limited to V_{DD} for performing the short bar test. Supplying V_{SS} or other voltages valid for switching on the switching devices serve to perform short bar test is also within the scope of the present invention.

In the embodiment of the present invention, the operation method further includes providing a control voltage, e.g. V_{DD}, to the shorting bar signal source terminal then to the gate terminal of the switch devices S₁˜Sₙ of the testing apparatus in step s180, and determining whether to turn on or off the switch devices S₁˜Sₙ according to the voltage given at the shorting bar signal source via probing terminal 112 from a testing bed (not shown) in step s182. In step s184, when the switch devices S₁˜Sₙ are turned off, the probing terminals serve for measuring inputting image signals provided from the image signal source via the probing terminal 114, i.e. performing the full contact test. On the contrary, in step s186 when the switch devices are turned on by the control voltage, e.g. V_{DD}, given at the shoring bar signal source terminal via the probing terminal 112, the probing terminals serve for the full contact test. It is noted that the control voltage given at the shorting bar signal source is not limited to V_{SS} for performing the full contact test. Supplying V_{DD} or other voltages valid for switching off the switching devices serve to perform full contact test is also within the scope of the present invention.

Accordingly, the testing apparatus for testing a display and the operation method of the testing apparatus can switch between testing modes, e.g. shorting bar test and full contact test, according to different control instructions given by a testing bed (not shown in FIG. 1A) feeding the shorting bar signal source terminal.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A testing apparatus, electrically coupled to a first driving line of a display, an image signal source and a shorting bar signal source, comprising:
a first bonding pad, electrically coupled to the first driving line;
a probing terminal, electrically coupled to the first bonding pad; and
a switch device, having a gate terminal, a first terminal and a second terminal, wherein the gate terminal is electrically coupled to the shorting bar signal source, the first terminal is electrically coupled to the image signal source, the second terminal is electrically coupled to the probing terminal.

2. The testing apparatus of claim 1, wherein the testing apparatus is controlled by a voltage from the shorting bar signal source for serving a shorting bar test or a full contact test.

3. The testing apparatus of claim 2, wherein the switch device is turned on for serving the shorting bar test when the shorting bar signal source provides a high voltage, and the switch device is turned off for serving the full contact test when the shorting bar signal source provides a low voltage.

4. The testing apparatus of claim 2, wherein when the shorting bar signal source provides a low voltage, the switch device is turned on for serving the shorting bar test, and when the shorting bar signal source provides a high voltage, the switch device is turned off for serving the full contact test.

5. The testing apparatus of claim 2 further comprising a second bonding pad electrically coupled to m probing terminals serving for the full contact test, wherein m is an integer not less than 1.

6. The testing apparatus of claim 2 further comprising a third bonding pad electrically coupled to s probing terminal serving for the full contact test, wherein s is an integer not less than 1.

7. The testing apparatus of claim 1, wherein the driving circuit is a data driving circuit.

8. The testing apparatus of claim 1, wherein the driving circuit is a gate driving circuit.

9. The testing apparatus of claim 1, wherein the display is a liquid crystal display or an organic light emitting display.

10. An operation method of a testing apparatus for testing a display, the testing apparatus comprising at least one switch device and at least one probing terminal, the operation method comprising;
providing a shorting bar signal source;
determining whether the switch device is turned on or off according to a voltage of the shorting bar signal source; and
determining whether to measure an image signal at the probing terminal according to whether the switch device is turned on or off.

11. The operation method of claim 10 further comprising performing a full contact test at the probing terminal when the switch device is turned off.

12. The operation method of claim 11 further comprising performing the full contact test at a second bonding pad and a third bonding pad.

13. The operation method of claim 10, wherein an image signal measurement is performed at the probing terminal when the switch device is turned on.

14. An integrated testing apparatus, for a display device having an array of display units, comprising:
a first test circuit, performing a shorting bar test;
a second test circuit, performing a full contact test; and
a switch device, configured to switch between a shorting bar test mode and a full contact test mode, thereby engaging respective one of the first test circuit and the second test circuits.

15. The integrated testing apparatus of claim 14, wherein the switch device switches between the shorting bar test mode and the full contact test mode in response to a control signal given by a testing bed.

16. The integrated testing apparatus of claim 15, wherein the switch device is turned on for serving the shorting bar test when the control signal provides a high voltage, and the switch device is turned off for serving the full contact test when the control signal provides a low voltage.

17. The integrated testing apparatus of claim 15, wherein when the control signal provides a low voltage, the switch device is turned on for serving the shorting bar test, and when the control signal provides a high voltage, the switch device is turned off for serving the full contact test.

18. The integrated testing apparatus of claim 14, wherein the shoring bar test mode comprises measuring an image signal.
